(19) United States
(12) Patent Application Publication
(10) Pub. No.: US 2013/0022835 A1
(43) Pub. Date: Jan. 24, 2013

(54) COATED ARTICLE HAVING ANTIBACTERIAL EFFECT AND METHOD FOR MAKING THE SAME

(71) Applicants: HSIN-PEI CHANG, Tu-Cheng (TW); WEN-RONG CHEN, Tu-Cheng (TW); CHENG-SHI CHEN, Tu-Cheng (TW); CONG LI, Shenzhen City (CN)

(72) Inventors: HSIN-PEI CHANG, Tu-Cheng (TW); WEN-RONG CHEN, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/210,756

(22) Filed: Aug. 16, 2011

(30) Foreign Application Priority Data
Jul. 20, 2011 (CN) 201110203618.4

(51) Int. Cl. B32B 15/04; C23C 14/14; C23C 14/08; C23C 14/35; B32B 7/02

(52) U.S. Cl. 428/622; 204/192.15

(57) ABSTRACT

A coated article is described. The coated article includes a substrate, a copper layer formed on the substrate, a compound copper-zinc layer formed on the copper layer, and a zinc oxide layer formed on the compound copper-zinc layer. A method for making the coated article is also described.

### CROSS-REFERENCE TO RELATED APPLICATIONS

This application is one of the four related co-pending U.S. patent applications listed below. All listed applications have the same assignee. The disclosure of each of the listed applications is incorporated by reference into the other listed applications.

| Attorney | | |
|---|---|---|
| Docket No. | Title | Inventors |
| US 37031 | COATED ARTICLE HAVING | HSIN-PEI |
| | ANTIBACTERIAL EFFECT AND METHOD | CHANG |
| | FOR MAKING THE SAME | et al. |
| US 39203 | COATED ARTICLE HAVING | HSIN-PEI |
| | ANTIBACTERIAL EFFECT AND METHOD | CHANG |
| | FOR MAKING THE SAME | et al. |
| US 39206 | COATED ARTICLE HAVING | HSIN-PEI |
| | ANTIBACTERIAL EFFECT AND METHOD | CHANG |
| | FOR MAKING THE SAME | et al. |
| US 40773 | COATED ARTICLE HAVING | HSIN-PEI |
| | ANTIBACTERIAL EFFECT AND METHOD | CHANG |
| | FOR MAKING THE SAME | et al. |

### BACKGROUND

1. Technical Field

The present disclosure relates to coated articles, particularly to a coated article having an antibacterial effect and a method for making the coated article.

2. Description of Related Art

To make the living environment more hygienic and healthy, a variety of antibacterial products have been produced by coating substrates of the products with antibacterial metal films. The metal may be copper (Cu), zinc (Zn), or silver (Ag). However, the metal ions within the metal films rapidly dissolve from killing bacterium, so the metal films have a short lifespan.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a coated article.

FIG. 2 is an overhead view of an exemplary embodiment of a vacuum sputtering device.

### DETAILED DESCRIPTION

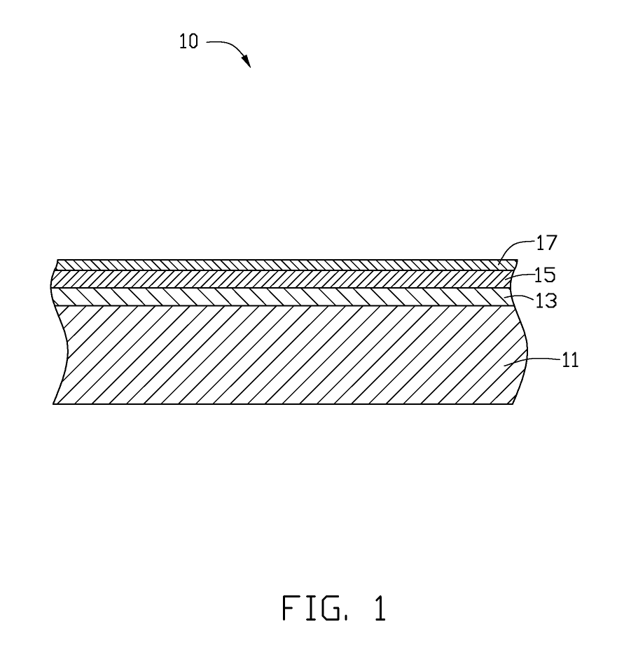

FIG. 1 shows a coated article 10 according to an exemplary embodiment. The coated article 10 includes a substrate 11, a copper (Cu) layer 13 formed on the substrate 11, a compound copper-zinc (Cu—Zn) layer 15 formed on the Cu layer 13, and a zinc oxide (ZnO) layer 17 formed on the Cu—Zn layer 15.

The substrate 11 may be made of stainless steel, but is not limited to stainless steel.

The copper layer 13 may be formed on the substrate 11 by vacuum sputtering. The copper layer 13 has a thickness of about 100 nm-250 nm. The copper layer 13 is securely bonded with the substrate 11.

The compound Cu—Zn layer 15 may be formed by vacuum sputtering. The compound Cu—Zn layer 15 may have a thickness of about 500 nm-800 nm. The Cu ions and Zn ions contained in the compound Cu—Zn layer 15 are all antibacterial ions, so the antibacterial effect of the coated article 10 is improved. Moreover, the copper within the compound Cu—Zn layer 15 further enhances the bond between the compound Cu—Zn layer 15 and the copper layer 13.

The ZnO layer 17 may be formed by vacuum sputtering. The ZnO layer 17 may have a thickness of about 70 nm-250 nm. The ZnO layer 17 inhibits the copper and zinc ions of the compound Cu—Zn layer 15 from rapidly dissolving, so the compound Cu—Zn layer 15 has long-lasting antibacterial effect. Furthermore, when irradiating, the ZnO layer 17 will be photo-catalyzed to kill bacterium, which further enhances and prolongs the antibacterial effect of the coated article 10.

A method for making the coated article 10 may include the following steps:

The substrate 11 is pre-treated, such pre-treating process may include the following steps:

The substrate 11 is cleaned in an ultrasonic cleaning device (not shown) filled with ethanol or acetone.

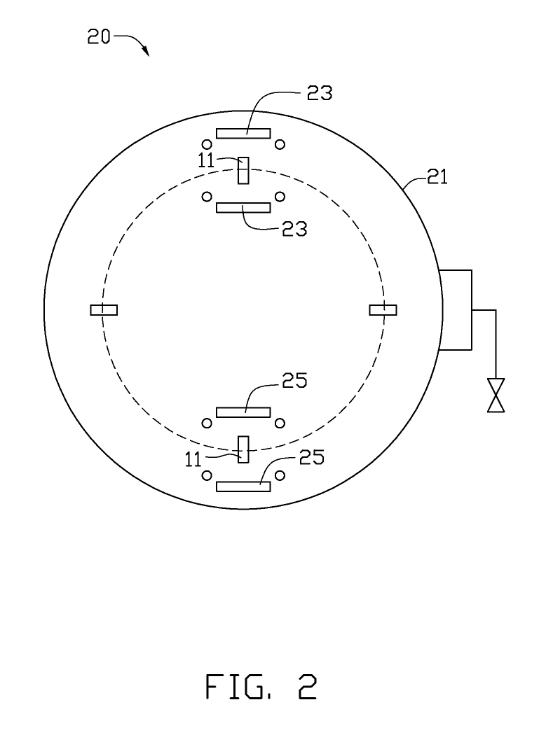

The substrate 11 is plasma cleaned. Referring to FIG. 2, the substrate 11 may be positioned in a coating chamber 21 of a vacuum sputtering device 20. The coating chamber 21 is fixed with copper (Cu) targets 23 and zinc (Zn) targets 25. The coating chamber 21 is evacuated to about 4.0×10⁻³ Pa. Argon gas (Ar) having a purity of about 99.999% may be used as a working gas and is fed into the coating chamber 21 at a flow rate of about 500 standard-state cubic centimeters per minute (sccm). The substrate 11 may have a bias voltage of about −200 V to about −350 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 3 minutes (min)-10 min. The plasma cleaning process enhances the bond between the substrate 11 and the copper layer 13. The Cu targets 23 and the Zn targets 25 are unaffected by the pre-cleaning process.

The copper layer 13 may be magnetron sputtered on the pretreated substrate 11 by using the copper targets 23. Magnetron sputtering of the copper layer 13 is implemented in the coating chamber 21. The inside of the coating chamber 21 is heated to about 50° C.-200° C. Argon gas may be used as a working gas and is fed into the coating chamber 21 at a flow rate of about 50 sccm-300 sccm. Power of about 0.5 kilowatt (KW) to about 5 KW is applied on the copper targets 23, and the copper atoms are sputtered off from the copper targets 23 to deposit on the substrate 11 and form the copper layer 13. During the depositing process, the substrate 11 may have a bias voltage of about −50 V to about −400 V. Depositing of the copper layer 13 may take about 1 min-5 min.

The compound Cu—Zn layer 15 may be magnetron sputtered on the copper layer 13 by using the copper targets 23 and zinc targets 25 simultaneously. Magnetron sputtering of the compound Cu—Zn layer 15 is implemented in the coating chamber 21. The internal temperature of the coating chamber 21 is maintained at about 50° C.-200° C. Argon gas may be used as a working gas and is fed into the coating chamber 21 at a flow rate of about 50 sccm-300 sccm. A power of about 0.5 KW-5 KW is applied on the copper targets 23, and another power of about 2 KW-12 KW is applied on the zinc targets 25. Then copper and zinc atoms are sputtered off from the copper targets 23 and zinc targets 25 simultaneously to deposit on the copper layer 13 and form the compound Cu—Zn layer 15. During the depositing process, the substrate 11 may have a bias voltage of about −50 V to about −400 V. Depositing of the compound Cu—Zn layer 15 may take about 10 min-90 min.

The ZnO layer 17 may be magnetron sputtered on the compound Cu—Zn layer 15 by using the Zn targets 25. Magnetron sputtering of the ZnO layer 17 is implemented in the coating chamber 21. The internal temperature of the coating chamber 21 is maintained at about 50° C.-200° C. Oxygen (0₂) may be used as a reaction gas and is fed into the coating chamber 21 at a flow rate of about 50 sccm-300 sccm. Argon gas may be used as a working gas and is fed into the coating chamber 21 at a flow rate of about 50 sccm-300 sccm. Power of about 2 KW-12 KW is applied on the Zn targets 25, and the Zn atoms are sputtered off from the Zn targets 25. The Zn atoms and oxygen atoms are ionized in an electrical field in the coating chamber 21. The ionized zinc then chemically reacts with the ionized oxygen to deposit on the compound Cu—Zn layer 15 and form the ZnO layer 17. During the depositing process, the substrate 11 may have a bias voltage of about −50 V to about −400 V. Depositing of the ZnO layer 17 may take about 1 min-15 min.

Specific examples of making the coated article 10 are described as follows. The pre-treating process of ultrasonic and plasma cleaning the substrate 11 in these specific examples may be substantially the same as previously described so it is not described here again. Additionally, the magnetron sputtering processes of the copper layer 13, compound Cu—Zn layer 15, and ZnO layer 17 in the specific examples are substantially the same as described above, and the specific examples mainly emphasize the different process parameters of making the coated article 10.

### Example 1

The substrate 11 is made of stainless steel.

Sputtering to form the copper layer 13 on the substrate 11: the flow rate of Ar is 300 sccm; the Cu targets 23 are applied with a power of 5 KW; the substrate 11 has a bias voltage of −200 V; the internal temperature of the coating chamber 21 is 100° C.; sputtering of the copper layer 13 takes 5 min; the copper layer 13 has a thickness of 250 nm.

Sputtering to form compound Cu—Zn layer 15 on the copper layer 13: the flow rate of Ar is 300 sccm; the substrate 11 has a bias voltage of −200 V; the Cu targets 23 are applied with a power of 5 KW, the Zn targets 25 are applied with a power of 8 KW; the internal temperature of the coating chamber 21 is 100° C.; sputtering of the compound Cu—Zn layer 15 takes 50 min; the compound Cu—Zn layer 15 has a thickness of 650 nm.

Sputtering to form ZnO layer 17 on the compound Cu—Zn layer 15: the flow rate of Ar is 300 sccm, the flow rate of O₂ is 250 sccm; the substrate 11 has a bias voltage of −200 V; the Zn targets 25 are applied with a power of 8 KW; the internal temperature of the coating chamber 21 is 100° C.; sputtering of the ZnO layer 17 takes 5 min; the ZnO layer 17 has a thickness of 70 nm.

### Example 2

The substrate 11 is made of stainless steel.

Sputtering to form the copper layer 13 on the substrate 11: the flow rate of Ar is 300 sccm; the Cu targets 23 are applied with a power of 5 KW; the substrate 11 has a bias voltage of −200 V; the internal temperature of the coating chamber 21 is 100° C.; sputtering of the copper layer 13 takes 5 min; the copper layer 13 has a thickness of 250 nm.

Sputtering to form compound Cu—Zn layer 15 on the copper layer 13: the flow rate of Ar is 300 sccm; the substrate 11 has a bias voltage of −200 V; the Cu targets 23 are applied with a power of 3 KW, the Zn targets 25 are applied with a power of 10 KW; the internal temperature of the coating chamber 21 is 100° C.; sputtering of the compound Cu—Zn layer 15 takes 50 min; the compound Cu—Zn layer 15 has a thickness of 700 nm.

Sputtering to form ZnO layer 17 on the compound Cu—Zn layer 15: the flow rate of Ar is 300 sccm, the flow rate of O₂ is 250 sccm; the substrate 11 has a bias voltage of −200 V; the Zn targets 25 are applied with a power of 8 KW; the internal temperature of the coating chamber 21 is 100° C.; sputtering of the ZnO layer 17 takes 5 min; the ZnO layer 17 has a thickness of 70 nm.

An antibacterial performance test has been performed on the coated articles 10 described in the above examples 1-2. The test was carried out as follows:

Bacteria was firstly dropped on the coated article 10 and then covered by a sterilization film and put in a sterilization culture dish for about 24 hours at a temperature of about 37±1° C. and a relative humidity (RH) of more than 90%. Secondly, the coated article 10 was removed from the sterilization culture dish, and the surface of the coated article 10 and the sterilization film were rinsed using 20 milliliter (ml) wash liquor. The wash liquor was then collected in a nutrient agar to inoculate the bacteria for about 24 hours to 48 hours at about 37±1° C. After that, the number of surviving bacteria was counted to calculate the bactericidal effect of the coated article 10.

The test result indicated that the bactericidal effect of the coated article 10 with regard to escherichia coli, salmonella, and staphylococcus aureus was no less than 99.9%. Furthermore, after having been immersed in water for about three months at about 37±1° C., the bactericidal effect of the coated article 10 on escherichia coli, salmonella, and staphylococcus aureus was no less than 98.2%.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A coated article, comprising:
a substrate; and
a copper layer formed on the substrate;
a compound copper-zinc layer formed on the copper layer, the compound copper-zinc layer being antibacterial; and
a zinc oxide layer formed on the compound copper-zinc layer, the zinc oxide layer inhibiting the compound copper-zinc layer from dissolving copper ions and zinc ions.

2. The coated article as claimed in claim 1, wherein the copper layer has a thickness of about 100 nm to about 250 nm.

3. The coated article as claimed in claim 1, wherein the compound copper-zinc layer has a thickness of about 400 nm to about 800 nm.

4. The coated article as claimed in claim 1, wherein the zinc oxide layer has a thickness of about 70 nm to about 250 nm.

5. The coated article as claimed in claim 1, wherein the substrate is made of stainless steel.

6. A method for making a coated article, comprising:
providing a substrate;
forming a copper layer on the substrate by vacuum sputtering, using a copper target;
forming a compound copper-zinc layer on the copper layer by vacuum sputtering, using a copper target and a zinc target; and
forming a zinc oxide layer on the compound copper-zinc layer by vacuum sputtering, using oxygen as a reaction gas and using a zinc target.

7. The method as claimed in claim 6, wherein forming the copper layer uses a magnetron sputtering method; the copper target is applied with a power of about 0.5 KW-5 KW; uses argon as a working gas, the argon has a flow rate of about 50 sccm-300 sccm; magnetron sputtering of the copper layer is conducted at a temperature of about 50° C.-200° C. and takes about 1 min-5 min.

8. The method as claimed in claim 7, wherein the substrate has a bias voltage of about −50V to about −400V during magnetron sputtering of the copper layer.

9. The method as claimed in claim 6, wherein forming the compound copper-zinc layer uses a magnetron sputtering method; the copper target is applied with a power of about 0.5 KW-5 KW; the zinc target is applied with a power of about 2 KW-12 KW; uses argon as a working gas, the argon has a flow rate of about 50 sccm-300 sccm; magnetron sputtering of the compound copper-zinc layer is conducted at a temperature of about 50° C.-200° C. and takes about 10 min-90 min.

10. The method as claimed in claim 9, wherein the substrate has a bias voltage of about −50V to about −400V during magnetron sputtering of the compound copper-zinc layer.

11. The method as claimed in claim 6, wherein forming the zinc oxide layer uses a magnetron sputtering method; the zinc target is applied with a power of about 2 KW-12 KW; the oxygen has a flow rate of about 50 sccm-300 sccm; uses argon as a working gas, the argon has a flow rate of about 50 sccm-300 sccm; magnetron sputtering of the zinc oxide layer is conducted at a temperature of about 50° C.-200° C. and takes about 1 min-15 min.

12. The method as claimed in claim 11, wherein the substrate has a bias voltage of about −50V to about −400V during magnetron sputtering of the zinc oxide layer.

13. The method as claimed in claim 6, further comprising a step of pre-treating the substrate before forming the copper layer.

14. The method as claimed in claim 13, the pre-treating process comprises ultrasonic cleaning the substrate and plasma cleaning the substrate.
